(19) United States
(12) Patent Application Publication
(10) Pub. No.: US 2009/0162962 A1
(43) Pub. Date: Jun. 25, 2009

(54) METHOD OF MANUFACTURING NITRIDE SEMICONDUCTOR LASER

(75) Inventors: Yosuke SUZUKI, Tokyo (JP); Yasuyuki NAKAGAWA, Tokyo (JP); Kyosuke KURAMOTO, Tokyo (JP); Takeo SHIRAHAMA, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/325,354

(22) Filed: Dec. 1, 2008

(30) Foreign Application Priority Data
Dec. 19, 2007 (JP) 2007-327050

(51) Int. Cl. H01L 21/02

(52) U.S. Cl. 438/46; 257/E21.002

(57) ABSTRACT

The invention provides a high-reliability nitride semiconductor laser that reduces the stress of a nitride dielectric film formed on a resonator's end face, thus reducing possible damage to the resonator's end face, which may occur during the formation of the nitride dielectric film. A method of manufacturing a nitride semiconductor laser according to the invention uses a nitride-based III-V compound semiconductor and includes the steps of (a) forming an adherence layer of a nitride dielectric on both a light-emitting and a light-reflecting end face of a resonator in plasma containing a nitrogen gas; and (b) forming a low-reflective and a high-reflective face-coating film of a dielectric on the adherence layers.

### BACKGROUND OF THE INVENTION

1. Field of the Invention

The present invention relates to a method of manufacturing a nitride semiconductor laser using a nitride-based III-V compound semiconductor.

2. Description of the Background Art

A Conventional nitride-based III-V compound semiconductor laser has an adherence layer formed between a resonator's end face and a face-coating film, thereby preventing degradation in the resonator's end face due to instantaneous optical damage.

One example is a configuration having an isolating layer of aluminum nitride formed between a resonator's end face and a face-coating film of aluminum oxide (cf. Japanese Patent Application Laid-open No. 2007-103814.)

As described in Japanese Patent Application Laid-open No. 2007-103814, a common method for forming a film by sputtering on a resonator's end face uses an argon (Ar) gas as a sputtering gas, because the use of a high-mass gas will improve the sputtering speed. However, during the application of Ar plasma containing an Ar gas to a resonator's end face, the Ar plasma collides with and gives damage to the resonator's end face, inducing surface recombination due to the generation of a trap level and thereby causing degradation in the resonator's end face at the occurrence of laser emission.

Besides, since a film of a nitride dielectric generally has a high stress, a nitride dielectric film formed in Ar plasma will include Ar as interstitial atoms. This can cause distortion in a nitride dielectric film sputtered on a resonator's end face and is thus likely to produce undesirable results such as peeling-off of and cracks in the film. From this, high controllability is required for film formation.

### SUMMARY OF THE INVENTION

It is an object of the invention to provide a method of manufacturing a high-reliability nitride semiconductor laser that reduces the stress of a nitride dielectric film formed on a resonator's end face, thus reducing possible damage to the resonator's end face, which may occur during the formation of the nitride dielectric film.

A method of manufacturing a nitride semiconductor laser according to the invention uses a nitride-based III-V compound semiconductor and includes the steps of: (a) forming an adherence layer of a nitride dielectric on a resonator's end face in plasma containing a nitrogen gas; and (b) forming a coating film of a dielectric on the adherence layer.

The step of forming an adherence layer of a nitride dielectric on a resonator's end face in plasma containing a nitrogen gas and the step of forming a coating film of a dielectric on the adherence layer, according to the invention, can reduce the stress of a nitride dielectric film formed on the resonator's end face, thus reducing possible damage to the resonator's end face, which may occur during the formation of the nitride dielectric film.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a configuration of a nitride semiconductor laser according to a first preferred embodiment of the invention;

FIG. 2 is a cross-sectional view of a resonator in the nitride semiconductor laser according to the first preferred embodiment of the invention;

FIG. 3 illustrates a general configuration of the nitride semiconductor laser according to the first preferred embodiment of the invention; and

FIG. 4 is a cross-sectional view of a resonator in a nitride semiconductor laser according to a second preferred embodiment of the invention.

### DESCRIPTION OF THE PREFERRED EMBODIMENTS

Preferred embodiments of the invention are described with reference to the drawings.

### First Preferred Embodiment

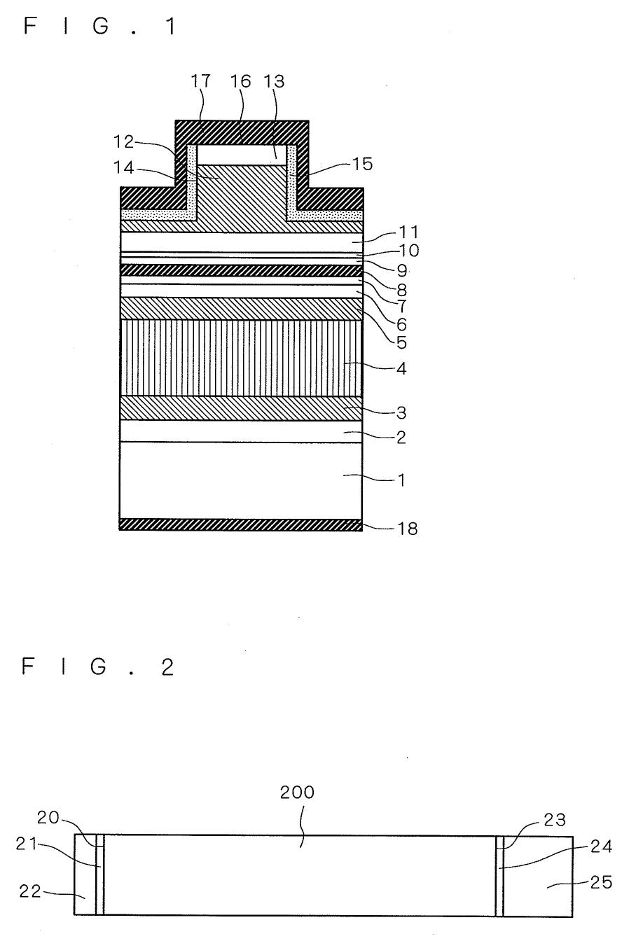

FIG. 1 is a cross-sectional view illustrating a configuration of a semiconductor laser (semiconductor light-emitting device) manufactured using a nitride-based III-V compound semiconductor according to a first preferred embodiment of the invention. The semiconductor laser according to the present preferred embodiment has ridges and SCHs (separate confinement heterostructures).

As illustrated in FIG. 1, an n-type GaN buffer layer 2 is formed on one main surface of a GaN substrate 1. For the flattest possible deposition on that main surface of the GaN substrate 1, the n-type GaN buffer layer 2 is formed so as to reduce roughness on the main surface of the GaN substrate 1. The n-type GaN buffer layer 2 may have a thickness of, for example, 1 μm and may be doped with silicon (Si) as an n-type dopant.

On the n-type GaN buffer layer 2, an n-type AlGaN cladding layer 3 which contains Al at the composition rate of 0.07, an n-type AlGaN cladding layer 4 which contains Al at the composition rate of 0.045, and an n-type AlGaN cladding layer 5 which contains Al at the composition rate of 0.015 are formed by successive laminations. The n-type AlGaN cladding layers 3, 4, and 5 may have a thickness of, for example, 0.4, 1.0, and 0.3 μm, respectively, and may be doped with Si as an n-type dopant.

Then, an n-type GaN light guide layer 6 and an n-type InGaN-SCH layer 7 are formed by successive laminations on the n-type AlGaN cladding layer 5. The n-type InGaN-SCH layer 7 may for example have a thickness of 30 nm and contain In at the composition rate of 0.02 and may be undoped. On the n-type InGaN-SCH layer 7 is formed an active layer 8. The active layer 8 may, for example, have a double-quantum-well structure including a 5.0-nm-thick InGaN well layer and a 8.0-nm-thick InGaN barrier layer.

On the active layer 8, a p-type InGaN-SCH layer 9, a p-type AlGaN electron barrier layer 10, and a p-type GaN light guide layer 11 are formed by successive laminations. The p-type InGaN-SCH layer 9 may for example have a thickness of 30 nm and contain In at the composition rate of 0.02 and may be undoped; the p-type AlGaN electron barrier layer 10 may for example have a thickness of 20 nm and contain Al at the composition rate of 0.2 and may be doped with magnesium (Mg) as a p-type dopant.

On the p-type GaN light guide layer 11 is formed a p-type AlGaN cladding layer 12 which contains Al at the composition rate of 0.07. The p-type AlGaN cladding layer 12 has a partly projecting ridge 14, on which then a p-type GaN contact layer 13 is formed. The ridge 14 is configured of the p-type AlGaN cladding layer 12 and a p-type GaN contact layer 13 in such a manner that the p-type AlGaN cladding layer 12 and the p-type GaN contact layer 13 are formed by successive laminations on the p-type GaN light guide layer 11, and then they are etched, for example along a <1-100> direction. The ridge 14 is formed to be located on a low-density defect zone between high-density dislocation zones formed with a width of several to dozen μm in strips on the GaN substrate 1. The p-type GaN light guide layer 11 may have a thickness of, for example, 100 nm. The p-type AlGaN cladding layer 12 may have a thickness of, for example, 500 nm and may be doped with Mg as a p-type dopant. The p-type GaN contact layer 13 may have a thickness of, for example, 20 nm, and may be doped with Mg as a p-type dopant.

On the surface of the ridge 14 other than an opening 16, i.e., on the side face of the ridge 14, is formed an insulator film 15. Then, a p-type electrode 17 is formed to cover the p-type GaN contact layer 13 and the insulator film 15. The insulator film 15 may be formed of, for example, a SiO₂ film with a thickness of 200 nm; the p-type electrode 17 may have a laminated structure including, for example, palladium (Pd) and gold (Au).

On the other main surface, namely, an N plane, of the GaN substrate 1, opposite the above main surface, namely a Ga plane, is formed an n-type electrode 18. The n-type electrode 18 may have a laminated structure including, for example, titanium (Ti) and gold (Au).

After the fabrication of the above nitride semiconductor laser structure, the substrate surface is cut for cleavage, for example using a diamond scriber, thereby forming a resonator. The resonator may have a length of 800 nm.

FIG. 2 is a cross-sectional view along the direction in which the resonator resonates in the nitride semiconductor laser according to the first preferred embodiment (the direction perpendicular to the plane of FIG. 1). As illustrated in FIG. 2, an adherence layer 21 of aluminum nitride (a nitride dielectric) is formed on a light-emitting end face 20 of the resonator in plasma containing a nitrogen gas, and then a low-reflective face-coating film 22 (coating film) is formed on the adherence layer 21. Similarly, an adherence layer 24 of aluminum nitride (a nitride dielectric) is formed on a light-reflecting end face 23 of the resonator in plasma containing a nitrogen gas, and then a high-reflective face-coating film 25 (coating film) is formed on the adherence layer 24.

Next, a method of manufacturing the resonator in FIG. 2 is described in detail.

A semiconductor laser bar 200 formed by cleavage is fixed to a jig so that the light-emitting end face 20 becomes a film-forming plane. The bar is then introduced into a film-forming chamber in an ECR (electron cyclotron resonance) sputtering apparatus, from which then air is exhausted using a vacuum pump.

After air was exhausted by a vacuum pump to place the film-forming chamber under vacuum, a gas containing nitrogen is introduced into the chamber in the ECR sputtering apparatus at a flow rate of about 10 sccm and a 500-W microwave is applied to generate nitrogen plasma. Then, 500-W RF (radio frequency) power is applied to sputter a target of aluminum. The sputtered aluminum is ionized and drifts with the plasma flow toward the jig to which the laser bar 200 is fixed. The aluminum sputtered in the nitrogen gas is deposited on the light-emitting end face 20 as the adherence layer 21 of aluminum nitride.

Then, the low-reflective face-coating film 22 is formed on the adherence layer 21. Since the light-emitting end face 20 is protected by the adherence layer 21, an ECR sputter deposition method using an Ar gas may be employed for the formation of the low-reflective face-coating film 22. Alternatively, the jig that has fixed the semiconductor laser bar 200 may be removed from the ECR sputtering apparatus after the formation of the adherence layer 21, and the formation of the low-reflective face coating film 22 may be done with the aid of an electron-beam deposition apparatus, a CVD (chemical vapor deposition) apparatus, and an RF sputtering apparatus.

The low-reflective face-coating film 22 may be a single-layer dielectric selected from the group including aluminum oxide, aluminum oxynitride, silicon nitride, silicon oxide, tantalum oxide, titanium oxide, and the like; or may be a multi-layer film formed by lamination of those dielectrics. When the reflectivity of the low-reflective face-coating film 22 takes any arbitrary design value, the thickness of the film 22 is determined according to that design value. For instance, when the adherence layer 21 of aluminum nitride has a thickness of 10 nm and the low-reflective face-coating film 22 of aluminum oxide 74 nm, the low-reflective face-coating film 22 has a reflectivity of about 5%.

As an alternative, a surface cleaning process either using nitrogen plasma or by heating may be done before the film formation described above.

Next, the semiconductor laser bar 200 is fixed to a jig so that the light-reflecting end face 23 becomes a film-forming plane, and as in a similar manner to the formation of the adherence layer 21, nitrogen plasma is generated by the introduction of a gas containing nitrogen into the evacuated film-forming chamber at a flow rate of 100 sccm and by the application of a 500 W microwave. Then, 500-W RF power is applied to sputter a target of aluminum to thereby form an adherence layer 24 of aluminum nitride on the light-reflecting end face 23.

Subsequently, the high-reflective face-coating film 25 is formed on the adherence layer 24. The high-reflective face-coating film 25 is formed of at least a pair of dielectrics having different reflectivities, which are selected from the group including aluminum (Al) nitride, Al oxide, and Al oxynitride; silicon (Si) nitride, Si oxide, and Si oxynitride; tantalum (Ta) nitride, Ta oxide, and Ta oxynitride; titanium (Ti) nitride, Ti oxide, and Ti oxynitride; niobium (Nb) nitride, Nb oxide, and Nb oxynitride; zirconium (Zr) nitride, Zr oxide, and Zr oxynitride; hafnium (Hf) nitride, Hf oxide, and Hf oxynitride; zinc (Zn) nitride, Zn oxide, and Zn oxynitride; and the like. By adjusting the total thickness of a pair of dielectrics having different reflectivities to a thickness equal to half the wavelength of emitting light, reflected light becomes brighter at the light-reflecting end face 23; and lamination of such a pair of dielectrics allows efficient formation of a high-reflective film. For instance, lamination of five pairs of 68 nm silicon oxide and 48 nm tantalum oxide provides a high-reflective film having a 95-percent reflectivity. Alternatively, another dielectric may be inserted before and after each pair to control the reflectivity.

The adherence layers 21 and 24 each may be formed of any nitride dielectric film containing no Ar by the use of a nitrogen gas for film formation and may be formed of not only aluminum nitride but also any one of tantalum nitride, titanium nitride, silicon nitride, niobium nitride, and zirconium nitride. While the first preferred embodiment has shown the case where the order of formation is first the light-emitting end face 20 side and then the light-reflecting end face 23 side, the order may be reversed.

As described so far, not an Ar gas but a nitrogen gas having a smaller mass than Ar is used in sputtering for the formation of the adherence layers 21 and 24, which reduces possible sputtering damage to the resonator's end face. Besides, since there is no possibility that the adherence layers 21 and 24 of aluminum nitride include Ar, the stress of aluminum nitride is only the internal stress specific to the material. Thus, controlling the stress depending on the film-forming conditions will relax restrictions on the film thickness, thus preventing a decrease in productivity due to the necessity of thickness control of the adherence layers.

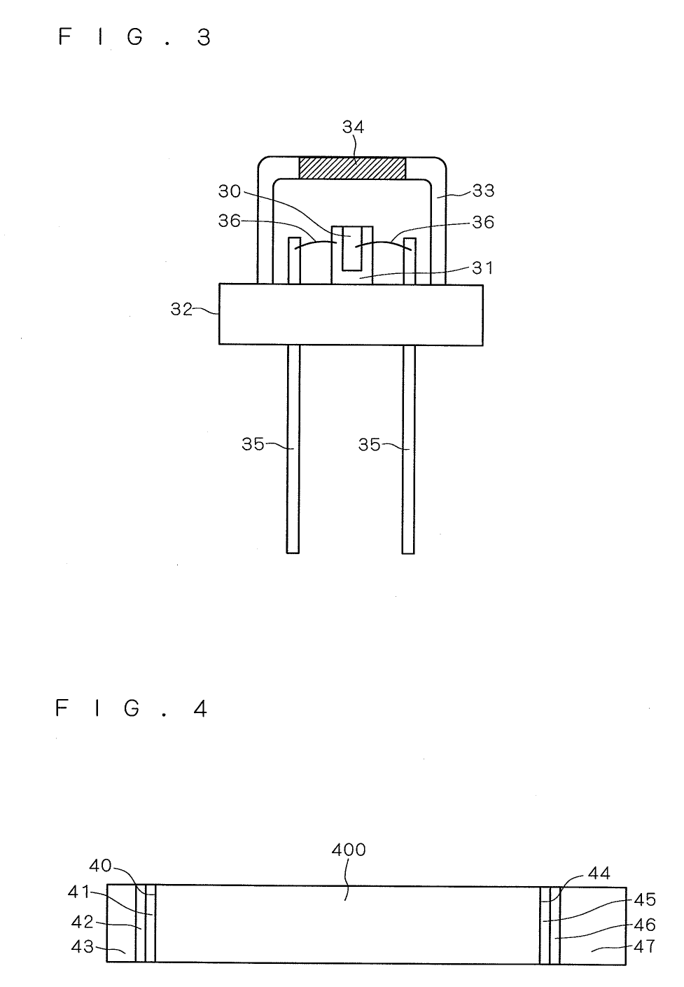

The semiconductor laser bar 200 fabricated with the above manufacturing method is divided into chips. FIG. 3 illustrates a general configuration of a nitride semiconductor laser according to the first preferred embodiment of the invention. As illustrated in FIG. 3, a laser device 30 is fixed on a sub-mount 31 of AlN or SiC, which is then attached to a stem 32. The sub-mount 31 and lead pins 35 are electrically connected via interconnect lines 36. The laser device 30 is packaged by being sealed airtight with a cap 33 having a glass window 34 that transmits light to the outside. The package is filled with a gas such as oxygen, nitrogen, or an inert gas.

### Second Preferred Embodiment

The second preferred embodiment is characterized in that, in forming an adherence layer on a resonator's end face with the aid of an ECR sputtering apparatus, two-phase RF power is applied for sputtering of a target so that the adherence layer is formed at multi-level growth rates, from a low-speed film-forming phase to a high-speed film-forming phase. The other steps are the same as those in the first preferred embodiment.

FIG. 4 is a cross-sectional view of a resonator in a nitride semiconductor laser according to a second preferred embodiment of the invention. As illustrated in FIG. 4, on a light-emitting end face 40 of the resonator is formed a first adherence layer 41 of a nitride dielectric containing no Ar, on the surface of which then a second adherence layer 42 of a nitride dielectric is formed at a higher rate than the first adherence layer 41. Then, a low-reflective face-coating film 43 is formed on the surface of the second adherence layer 42.

On a light-reflecting end face 44 of the resonator is formed a first adherence layer 45 of a nitride dielectric containing no Ar, on the surface of which then a second adherence layer 46 of a nitride dielectric is formed at a higher rate than the first adherence layer 45. Then, a high-reflective face-coating film 47 is formed on the surface of the second adherence layer 46.

The first adherence layers 41 and 45 and the second adherence layers 42 and 46 are formed of any one of aluminum nitride, tantalum nitride, titanium nitride, silicon nitride, niobium nitride, and zirconium nitride.

Next, a method of manufacturing the resonator in FIG. 4 is described in detail.

A semiconductor laser bar 400 formed by cleavage is fixed to a jig so that the light-emitting end face 40 becomes a film-forming plane, and then is introduced into a film-forming chamber in an ECR sputtering apparatus, from which then air is exhausted using a vacuum pump.

After air was exhausted by a vacuum pump to place the film-forming chamber under vacuum, a gas containing nitrogen is introduced into the chamber in the ECR sputtering apparatus at a flow rate of about 10 sccm and a 500-W microwave is applied to generate nitrogen plasma. Then, 50-W RF power is applied to sputter a target of aluminum to thereby deposit aluminum nitride, which is the adherence layer 41, to a thickness of, for example, 2 nm. After the formation of the first adherence layer 41, the RF power applied to a target is increased to 500 W to increase the sputter deposition rate, so that the second adherence layer 42 of aluminum nitride is formed at a higher rate than the first adherence layer 41. At this time, since the light-emitting end face 40 is protected by the first adherence layer 41, possible plasma damage to the light-emitting end face 40 can be suppressed even if the second adherence layer 42 is deposited at a higher rate.

After the formation of the second adherence layer 42, the low-reflective face-coating film 43 is formed on the adherence layer 42. This method is identical to that of forming the low-reflective face-coating film 22 described in the first preferred embodiment.

Then, the semiconductor laser bar 400 is fixed to a jig so that the light-reflecting end face 44 becomes a film-forming plane, and nitrogen plasma is generated by the introduction of a gas containing nitrogen into the evacuated chamber in the ECR sputtering apparatus at a flow rate of 10 sccm and by the application of a 500-W microwave. Then, 500-W RF power is applied to a target of aluminum to thereby form the first adherence layer 45 of aluminum nitride on the light-reflecting end face 44. After the formation of the first adherence layer 45, the RF power applied to a target is increased to 500 W to increase the sputter deposition rate, so that the second adherence layer 46 of aluminum nitride is formed at a higher rate than the first adherence layer 45.

After the formation of the second adherence layer 46, the high-reflective face-coating film 47 is formed on the second adherence layer 46. The method of forming the high-reflective face-coating film 47 is the same as that of forming the high-reflective face-coating film 25 described in the first preferred embodiment.

While the second preferred embodiment has shown the case where the order of formation is first the light-emitting end face 40 side and then the light-reflecting end face 44 side, the order may be reversed. Furthermore, the formation of the first adherence layers 41 and 45 should desirably be implemented at low-power deposition rates that are applicable to a volume production process.

From the above, although the deposition rate decreases because RF power applied to a target is reduced during the formation of the first adherence layers 41 and 45, possible plasma damage to both the light-emitting end face 40 and the light-reflecting end face 44 can yet be reduced. By, in this way, forming the adherence layers at multi-level growth rates from a low-speed film-forming phase to a high-speed film-forming phase, the effects discussed in the first preferred embodiment can further be improved.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a nitride semiconductor laser using a nitride-based III-V compound semiconductor, the method comprising the steps of:
(a) forming an adherence layer of a nitride dielectric on a resonator's end face in plasma containing a nitrogen gas; and
(b) forming a coating film of a dielectric on said adherence layer.

2. The method of manufacturing a nitride semiconductor laser according to claim 1, wherein
in said step (a), said adherence layer is formed of any one of aluminum nitride, tantalum nitride, silicon nitride, niobium nitride, and zirconium nitride.

3. The method of manufacturing a nitride semiconductor laser according to claim 1, wherein
in said step (b), said coating film is formed in plasma formed from a gas containing an argon gas.

4. The method of manufacturing a nitride semiconductor laser according to claim 1, wherein
said step (a) generates said adherence layer at multi-level growth rates, from a low-speed film-forming phase to a high-speed film-forming phase.

5. The method of manufacturing a nitride semiconductor laser according to claim 1, wherein
said step (a) uses an ECR (electron cyclotron resonance) sputtering apparatus.
